(19) United States
(12) Patent Application Publication
(10) Pub. No.: US 2024/0379360 A1
(43) Pub. Date: Nov. 14, 2024

(54) Ohmic Contact for Semiconductor Structures

(71) Applicant: Applied Materials, Inc., Santa Clara, CA (US)

(72) Inventor: Shiva RAI, Fremont, CA (US)

(21) Appl. No.: 18/196,187

(22) Filed: May 11, 2023

(51) Int. Cl. H01L 21/04; H01L 21/02; H01L 29/66

(52) U.S. Cl. CPC H01L 21/0485; H01L 21/02266; H01L 21/02458; H01L 21/0254; H01L 29/66462

(57) ABSTRACT

A method for forming an ohmic contact of a semiconductor structure leverages physical vapor deposition films. In some embodiments, the method may comprise forming at least one recess in a III-V semiconductor material on a substrate, forming a mask on the semiconductor material where at least the recess is left unmasked, depositing a contact transition layer of a metal nitride material in the recess using a physical vapor deposition (PVD) process, and forming a metal layer on the contact transition layer to form the ohmic contact. The ohmic contact may be formed for use in a high electron mobility transistor (HEMT), a light emitting diode (LED), and/or laser-based structures and the like. The contact transition layer may be doped or undoped material depending on the metal nitride variant used as the contact transition layer material.

### FIELD

Embodiments of the present principles generally relate to semiconductor processing of semiconductor substrates.

### BACKGROUND

Electronic devices, and even photonic devices, often have metal contacts that interact with semiconductor materials creating a highly resistive interface. The high resistance of the contact directly impacts the performance of the device. A contact interface or contact transition layer may be used between the metal contact and the semiconductor material to make the contact less resistive. The inventor has observed, however, that the processes used to form the contact interface or contact transition layer are expensive and not conducive to large-scale manufacturing.

Accordingly, the inventor has provided methods and structures for improving contact performance while decreasing the cost of manufacturing.

### SUMMARY

Methods for improving the performance of a contact while reducing manufacturing costs of the contact are provided herein.

In some embodiments, a method for forming an ohmic contact of a semiconductor structure may comprise depositing a contact transition layer of a metal nitride material on a III-V semiconductor material using a physical vapor deposition (PVD) process and forming a metal layer on the contact transition layer to form the ohmic contact.

In some embodiments, the method may further include forming at least one recess on a substrate prior to depositing the contact transition layer and forming a mask on the substrate where the at least one recess is unmasked prior to depositing the contact transition layer, a mask that is a photoresist or dielectric material, an ohmic contact that is a source or drain of a high electron mobility transistor (HEMT), an ohmic contact that is a p-type contact or n-type contact of a light emitting diode (LED) structure or laser structure, a metal nitride material that is undoped hafnium nitride (HfN), a metal nitride material that is doped gallium nitride (GaN), a metal nitride material that is doped aluminum nitride (AlN) or indium nitride (InN), an ohmic contact that is a p-type contact and the metal nitride material is p-doped hafnium nitride (HfN), depositing the contact transition layer using a remote plasma PVD process, and/or depositing the contact transition layer at a temperature of approximately 300 degrees Celsius to approximately 900 degrees Celsius.

In some embodiments, a method for forming an ohmic contact of a semiconductor structure may comprise forming at least one recess in a semiconductor material of a high electron mobility transistor (HEMT) structure, forming a mask on the semiconductor material, wherein the at least one recess is unmasked, depositing a contact transition layer in the at least one recess using a physical vapor deposition (PVD) process with a remote plasma source, and forming a metal layer on the contact transition layer to form the ohmic contact for a source or drain of the HEMT.

In some embodiments, the method may further include a contact transition layer is undoped hafnium nitride (HfN), a contact transition layer that is doped gallium nitride (GaN), a contact transition layer that is aluminum nitride (AlN) or indium nitride (InN), and/or depositing the contact transition layer at a temperature of approximately 300 degrees Celsius to approximately 900 degrees Celsius.

In some embodiments, a non-transitory, computer readable medium having instructions stored thereon that, when executed, cause a method for forming an ohmic contact of a semiconductor structure to be performed, the method may comprise depositing a contact transition layer of a metal nitride material on a III-V semiconductor material using a physical vapor deposition (PVD) process and forming a metal layer on the contact transition layer to form the ohmic contact.

In some embodiments, the method of the non-transitory, computer readable medium may further include forming a recess in the semiconductor structure of a high electron mobility transistor (HEMT) structure prior to depositing the contact transition layer, forming a mask on the semiconductor structure prior to depositing the contact transition layer, wherein the recess is unmasked, depositing the contact transition layer in the recess using the physical vapor deposition (PVD) process with a remote plasma source, and forming the metal layer on the contact transition layer to form the ohmic contact for a source or drain of the HEMT. The method may also include a contact transition layer that is undoped hafnium nitride (HfN) or doped gallium nitride (GaN), and/or depositing the contact transition layer at a temperature of approximately 300 degrees Celsius to approximately 900 degrees Celsius.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method for forming an ohmic contact of a semiconductor structure in accordance with some embodiments of the present principles.

FIG. 2 depicts a cross-sectional view of a semiconductor structure in accordance with some embodiments of the present principles.

FIG. 3 depicts a cross-sectional view of the semiconductor structure with a mask in accordance with some embodiments of the present principles.

FIG. 4 depicts a cross-sectional view of the semiconductor structure with a contact transition layer in accordance with some embodiments of the present principles.

FIG. 5 depicts a cross-sectional view of the semiconductor structure with an ohmic contact in accordance with some embodiments of the present principles.

FIG. 6 depicts a cross-sectional view of a high electron mobility transistor in accordance with some embodiments of the present principles.

FIG. 7 depicts a cross-sectional view of a transistor operating in depletion mode in accordance with some embodiments of the present principles.

FIG. 8 depicts a cross-sectional view of a transistor with a p-gate operating in enhancement mode in accordance with some embodiments of the present principles.

FIG. 9 depicts a cross-sectional view of a transistor with a recessed gate operating in enhancement mode in accordance with some embodiments of the present principles.

FIG. 10 depicts a cross-sectional view of a light emitting diode in accordance with some embodiments of the present principles.

FIG. 11 depicts a physical vapor deposition chamber in accordance with some embodiments of the present principles.

FIG. 12 is a top-down view of an integrated tool in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and structures provide ohmic contacts with reduced resistivity and lower cost of manufacture. A contact transition layer between a metal contact layer and a semiconductor material is formed using a physical vapor deposition (PVD) process that is cost effective and conducive to large-scale manufacturing unlike current technologies. The methods of the present principles allow forming of contact transition layers at low deposition temperatures using highly conductive materials. The methods can be used in photonic and electronic-based devices alike using doped or undoped PVD formed contact transition layers.

In traditional, gallium nitride-based semiconductor structures, contact forming processes use n+ doped gallium nitride (GaN) that is regrown in recessed structures (e.g., trenches, etc.) to reduce contact resistance in III-Nitride devices, especially in high electron mobility transistors (HEMT) devices. Regrown GaN is expensive and not easily scalable to high volume manufacturing. However, the present methods and structures use PVD films (e.g., hafnium nitride (HfN), indium nitride (InN), aluminum nitride (AlN), GaN, etc.) in place of regrown films. The PVD films are formed with a low deposition temperature, optional doping, and at higher throughputs. Regrown GaN is typically formed using a molecular beam epitaxy (MBE) or metal organic chemical vapor deposition (MOCVD) process. Because MBE provides a higher performing contact transition layer than MOCVD, MBE is preferred over MOCVD in traditional contact forming processes. However, MBE is not useful for large-scale manufacturing processes because MBE is a low-volume, high-cost, research and development process.

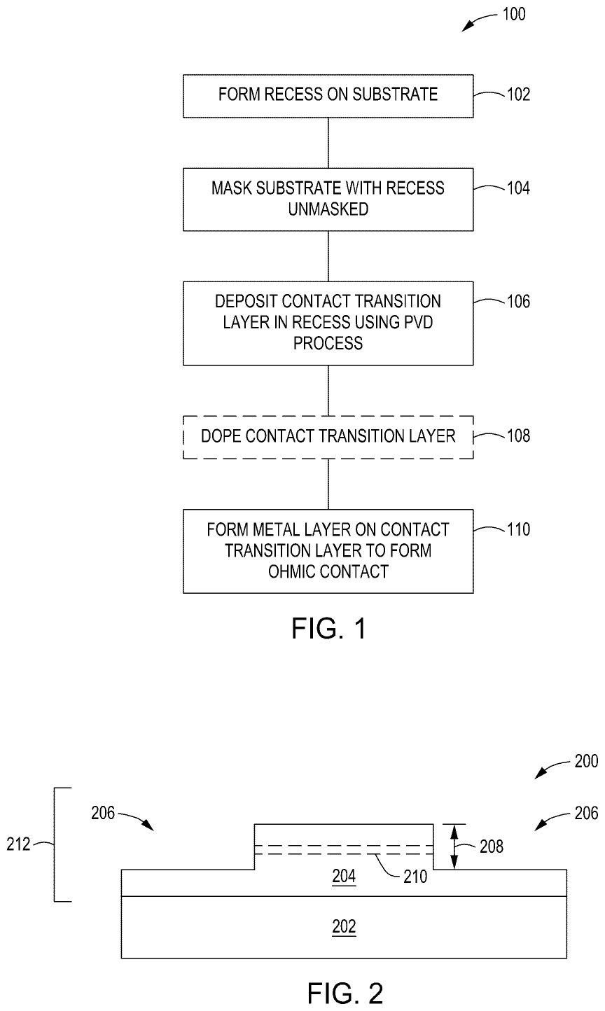

FIG. 1 is a method 100 for forming an ohmic contact using a PVD film as a contact transition layer of a metal nitride material. The contact transition layer facilitates reducing the resistance between a metal contact layer and, for example, a III-V semiconductor material layer. Lower resistance enhances performance of the semiconductor structure on which the contact is formed. The method 100 may be used for semiconductor structures such as, but not limited to, transistors, LEDs, lasers, and the like. References will be made to FIGS. 2-5 during discussion of the method 100. In block 102, a recess 206 is formed on a substrate 202 as depicted in a view 200 of FIG. 2. The substrate 202 may be silicon, sapphire, and/or silicon carbide, and the like. The recess 206 may be formed by etching and/or other processes to remove material in a layer such as, for example, semiconductor material layer 204. The semiconductor material layer 204 represents one or more material layers of the semiconductor structure 212 and is depicted as a single layer only for the sake of brevity in discussing the method 100. In some embodiments, the recess 206 is formed in a III-V semiconductor material. The recess 206 may be a hole, a trench, and/or another type of opening into the semiconductor material layer 204. The depth 208 of the recess 206 may be adjusted based on the type of semiconductor structure. For example, the semiconductor structure 212 depicted in FIG. 2 is a transistor and has a current channel 210. For optimum contact performance, the recess 206 has a depth 208 sufficient to expose the current channel 210 such that a contact transition layer makes contact with the current channel 210.

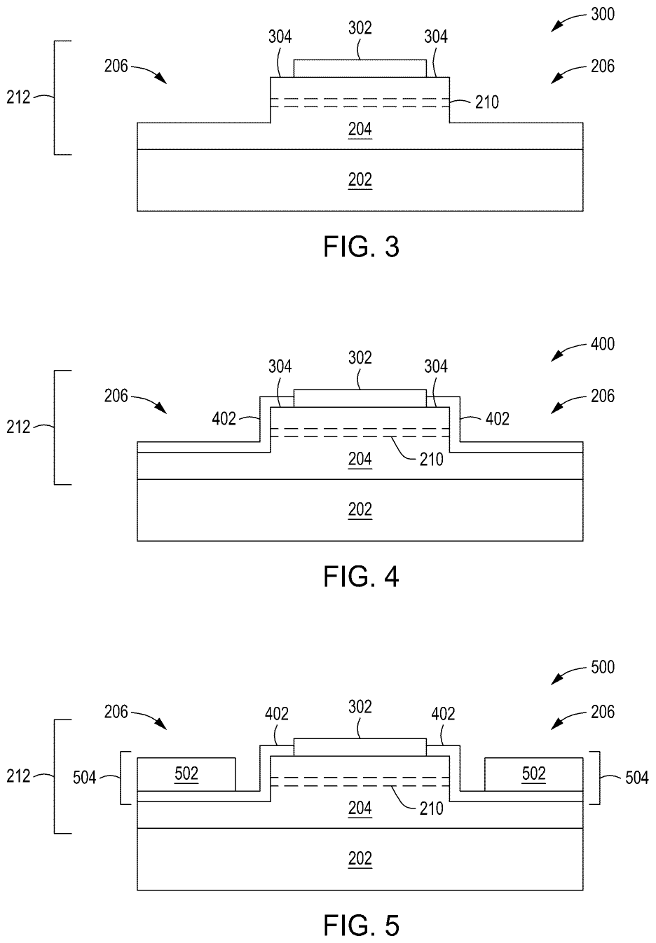

In block 104, a mask 302 is formed on the substrate 202 leaving at least the recess 206 exposed as depicted in a view 300 of FIG. 3. The mask 302 may be a photoresist mask and/or a dielectric layer formed to protect sensitive portions of the semiconductor structure 212 from subsequent PVD processes. In some embodiments, as depicted in FIG. 3, the mask 302 may have a reveal 304 adjacent the recess 206 for some types of semiconductor structures where a subsequent PVD film deposition process forms a film in the recess 206 and on the reveal 304. In block 106, a contact transition layer 402 is deposited at least in the recess 206 using a PVD deposition process as depicted in a view 400 of FIG. 4. In some embodiments, the contact transition layer 402 is a metal nitride material. A PVD deposition process is more cost-effective and scalable for large-scale manufacturing than MBE processes. And, for front-end-of-line (FEOL) manufacturers, PVD film does not require new or temperamental R&D-based equipment to produce the contact transition layer as with MBE processes. In some embodiments, the PVD deposition process is performed at a temperature of approximately 300 degrees Celsius to approximately 900 degrees Celsius. The low temperature of the PVD deposition process helps to preserve the thermal budget of the semiconductor structure during contact formation. PVD deposition is also faster than MBE or MOCVD regrowth processes, increasing manufacturing throughput. In the case of HfN PVD film, the resulting contact has lower resistance (higher conductivity) than regrown, doped GaN formed by MBE processes, substantially increasing the performance of a semiconductor structure.

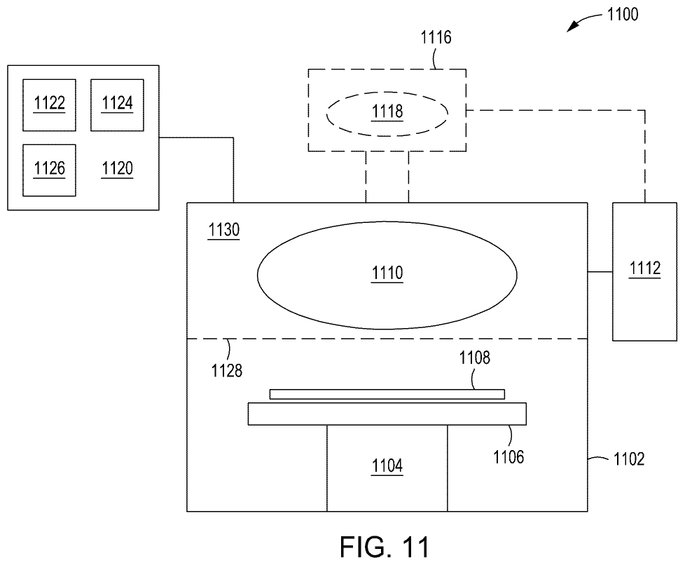

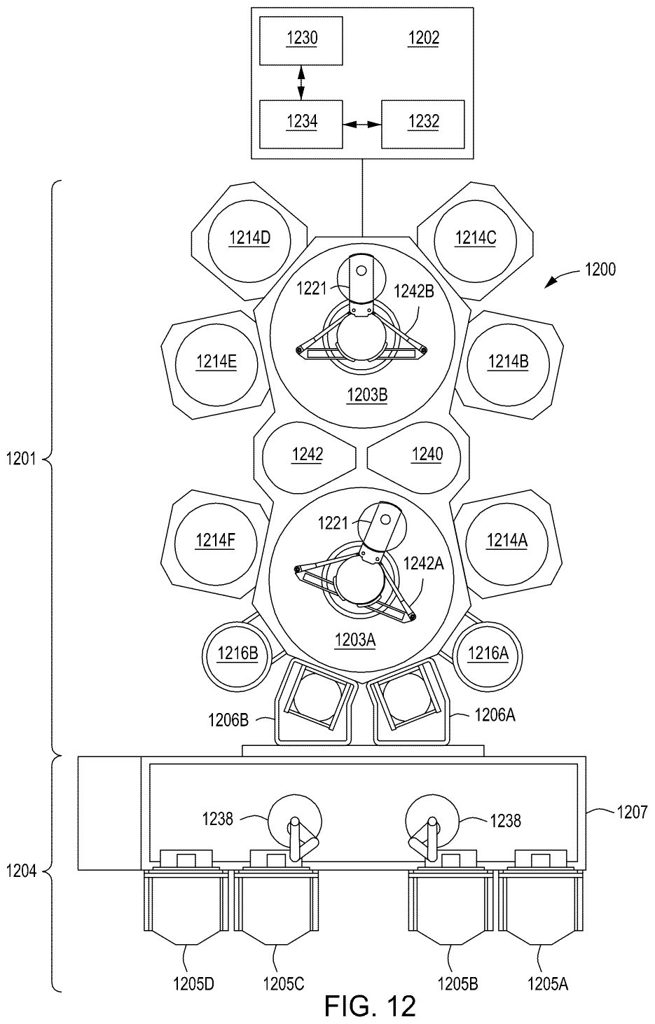

In some embodiments, the contact transition layer 402 is also deposited on the reveal 304 (as well as in the recess 206). The PVD deposition process may be performed in a PVD chamber (e.g., see FIG. 11) that utilizes local plasma or remote plasma for depositing the contact transition layer 402 on the substrate 202. In some embodiments, remote plasma may be used where sensitive portions of the semiconductor structure 212 are vulnerable to ion bombardment from local plasma. Use of the mask 302 facilitates reducing the effects of the ion bombardment and may mitigate the effects such that local plasma may be used. In optional block 108, in some embodiments, the contact transition layer 402 may be doped during and/or after deposition. Doping increases the conductivity of a metal nitride material selected for the contact transition layer. For n-type contacts, the contact transition layer 402 may be doped with silicon and the like to form an n+ contact transition layer. For p-type contacts, the contact transition layer 402 may be doped to form a p+ contact transition layer. In some embodiments, for materials such as HfN, the material is inherently n+ and no additional doping is required when using HfN PVD film for n-type contacts. If HfN PVD film is used for p-type contacts, the HfN PVD film is heavily doped to produce a p+ contact transition layer. GaN PVD film, undoped, is highly resistive. The GaN PVD film is doped n+ or p+ depending on use with an n-type contact or a p-type contact, respectively. InN PVD film is also doped n+ or p+ depending on use with an n-type contact or a p-type contact, respectively. In some embodiments, AlN can be used if doped appropriately. However, doping of AlN is very difficult with current technologies and may not be the most cost-effective choice of material for the contact transition layer. A change or advancement in technologies may make AlN a viable choice for the manufacturing of contacts.

Another consideration for selection of material for the contact transition layer is the bandgap value. GaN has a high bandgap value of 3.4 eV while HfN (1.8 eV) and InN (0.7 eV) have much lower bandgap values. The lower bandgap may impact photon-based semiconductor structures such as emitters (LEDs) and sensors. If, for example, a lower bandgap material is selected as a contact transition layer for a p-type contact of an LED, the contact transition layer may absorb photons, reducing the performance of the LED. Materials may be selected such that photon absorption is out of the range of the operating characteristics of the photon-based semiconductor structure or the low bandgap materials may be used with contacts that do not impede operation of the semiconductor structure when used as contact transition layers.

In block 110, a metal layer 502 is formed on the contact transition layer 402 to create an ohmic contact 504 as depicted in a view 500 of FIG. 5. The combination of the metal layer 502 and the contact transition layer 402 provides a low resistance contact to the semiconductor structure 212. In the example structure, the contact 504 may be used as a source or drain of a transistor (the depicted portions of the semiconductor structure 212 of FIG. 5 do not constitute a completed transistor). In some embodiments, the mask 302 may be removed prior to the forming of the metal layer 502. In some embodiments, the mask 302 may remain during the forming of the metal layer 502 to protect portions of the semiconductor structure 212 during formation of the metal layer 502.

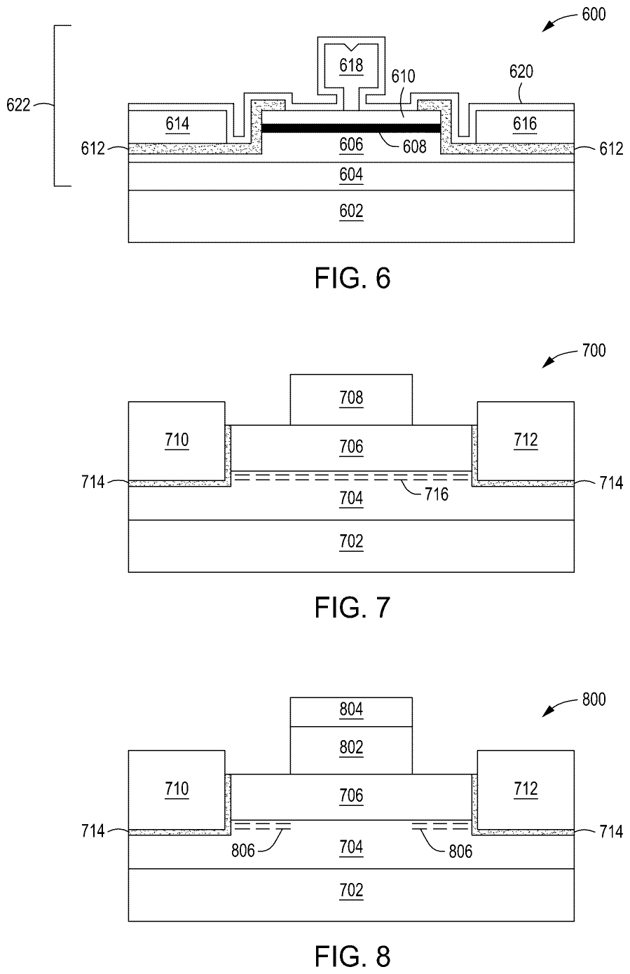

The method 100 may be used to provide low resistance contacts for different types of semiconductor structures such as a high electron mobility transistor (HEMT) 622 depicted in a view 600 of FIG. 6. The HEMT 622 is a GaN-based device that is formed on a substrate 602. A first semiconductor layer 604 may be formed, for example, of aluminum gallium nitride deposited on the substrate 602. A second semiconductor layer 606 is formed, for example, of GaN deposited on the first semiconductor layer 604. A resistive layer 610 may then be formed on the second semiconductor layer 606 and connected to a gate 618. During transistor operation, the conductive channel 608 is controlled by the gate 618. A source 614 and a drain 616 provide external contacts to the conductive channel 608. A contact transition layer 612 based on the present principles is formed in a recess on the second semiconductor layer 606 to form an ohmic contact between the conductive channel 608 and the source 614 and the drain 616. A dielectric layer 620 provides insulation to protect the HEMT 622. Performance of the HEMT 622 is enhanced by the contact transition layer 612 when formed as a PVD film. The lower resistance of the contacts allows the transistor to switch faster and to be more efficient (higher levels of current can flow through the conductive channel 608). Thus, when used in applications such as high frequency (HF) RF devices and beyond, the switching performance improvement provided by the contact transition layer of the present principles has a substantial impact on the HF RF device performance. When used in applications such as low frequency devices, such as power converters and the like, the lower resistance provided by the contact transition layer of the present principles has a substantial impact on the efficiency of the lower frequency device.

The methods disclosed herein may also be used to form structures such as a depletion mode transistor 700 of FIG. 7. A first semiconductor layer 704, such as for example GaN, is formed on a substrate 702. A second semiconductor layer 706, such as aluminum gallium nitride, is formed on the first semiconductor layer 704. Recesses formed into the second semiconductor layer 706 are lined with a PVD film to form a contact transition layer 714 for both a source 710 and a drain 712 to substantially reduce contact resistance and increase transistor performance. The depletion mode transistor 700 forms a two-dimensional electron gas (2DEG) channel 716 at the interface of the first semiconductor layer 704 and the second semiconductor layer 706. In another example of a semiconductor structure utilizing the present principles, an enhancement mode transistor 800 has a gate 708, for example a −p-n junction gate, that controls a current flow through a conductive channel 806 as depicted in FIG. 8. The gate contact 804 is formed with a p-GaN layer 802 to form a p-GaN gate for a transistor operating in enhancement mode. The contact transition layer 714 formed based on the present principles is used to lower the resistivity of the source 710 and drain 712 to provide a less resistive path for the 2DEG conductive channel 806. Similar to FIG. 8, another enhancement mode transistor 900 of FIG. 9 incorporates the contact transition layer 714. The contact transition layer 714 is formed based on the present principles to reduce contact resistance of both the source 710 and the drain 712 when using a recessed gate 902 with a dielectric layer 904. The gate recess depth in the transistor 900 depends on the performance criteria and could be as deep as the 2DEG conductive channel 806.

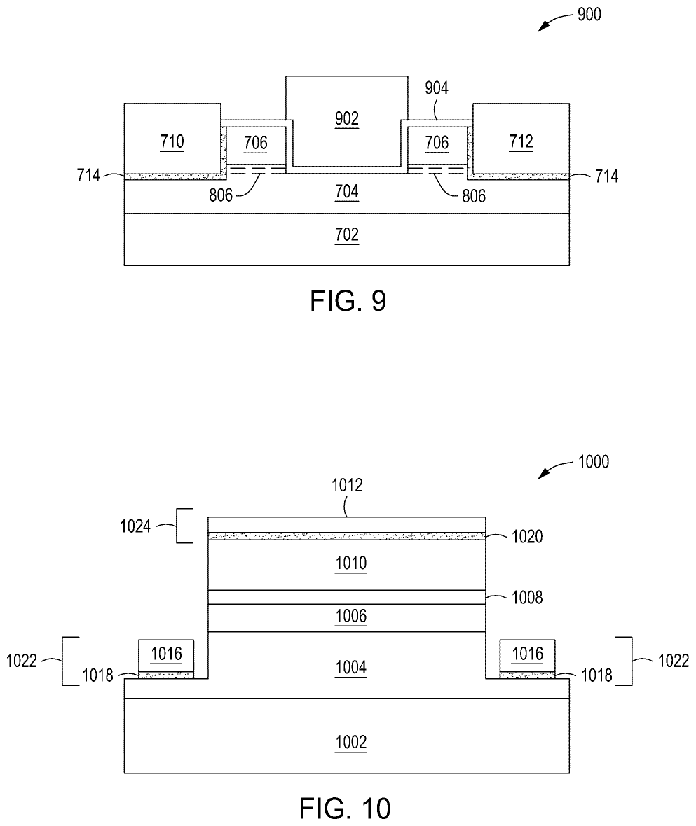

The method 100 may also be used with photon-based semiconductor structures such as the LED 1000 of FIG. 10. In the example of FIG. 10, an n-layer 1004 is deposited on a substrate 1002. The p-layer 1010 and the active layer 1008 are etched down to access the n-layer 1004 where a first contact transition layer 1018 has been formed according to the present principles. A first contact layer 1016 has then been formed on the contact transition layer 1018 to form a low resistance contact. In the example, the first low resistance contacts 1022 interface with the n-layer 1004 and are PVD films with either inherent n properties (HfN, etc.) or doped (GaN, InN, etc.) to have n properties. A quantum well layer 1006 is formed on the n-layer 1004, followed by the active layer 1008, and the p-layer 1010. A second contact transition layer 1020 is deposited by PVD on the p-layer 1010 according to the present principles. A second contact layer 1012 is then formed on the second contact transition layer 1020 to form the second low resistance contact 1024. The material selection of the second contact transition layer 1020 is selected to avoid absorption of photons within the operating range of the LED to mitigate effects of using lower bandgap materials such as HfN and InN and the like. Both HfN and InN are doped using p-dopants for use with the p-type contact. GaN may also be used when doped using p-dopants and has a much wider bandgap with less possible impact on LED performance than with other materials.

A PVD chamber 1100 of FIG. 11 is an example chamber that may be used for depositing the PVD films of the present principles. Other chambers may be used in conjunction with the PVD chamber 1100 to perform etching of the recesses and deposition of other materials. An integrated tool such as the integrated tool of FIG. 12 may be used to perform the method 100. The PVD chamber 1100 includes walls 1102 surrounding a substrate support 1104 with a substrate holder 1106 for supporting a substrate 1108. The walls 1102 also enclose a processing volume 1130 above the substrate support 1104. A gas source 1112 is fluidly connected to the processing volume 1130 and provides gases into the PVD chamber 1100 during processing of the substrate 1108 (or to the remote plasma source 1116). The gases supplied by the gas source 1112 may be used to directly form a PVD film on the substrate and/or to dope the PVD film as the PVD film is being deposited and/or after the PVD film has been deposited according to the type of semiconductor structure on the substrate 1108. In some embodiments, a plasma 1110 may be formed in the processing volume 1130. In some embodiments, the PVD chamber 1100 may have a dividing structure 1128 (e.g., a showerhead, collimator, etc.) that removes the plasma from direct interaction with the substrate 1108 and provides, in essence, a remote plasma for forming the PVD film of the contact transition layer. In some embodiments, a remote plasma source 1116 may be attached to the PVD chamber 1100 and produce a remote plasma 1118. Remote plasma may be preferred when the semiconductor structure has sensitive portions where direct ion bombardment is not desired. If masking of the sensitive portions is performed, the masking may allow the use of local plasma rather than remote plasma.

The controller 1120 allows different process recipes to be used based, for example, on the types of semiconductor structures being processed (e.g., selection of different gases/amounts, and the like) and the materials used for the contact transition layer (e.g., doped/undoped materials, p-dopants, n-dopants, etc.) and the like. Temperature of the PVD deposition process can also be precisely controlled within the approximately 300 degrees Celsius to approximately 900 degrees Celsius temperature window to preserve the thermal budgets of the semiconductor structures on the substrates. Selection of deposition materials, doping, and temperature may be automated based on the type of semiconductor structure being processed.

The controller 1120 achieves the aforementioned by controlling the operation of the PVD chamber 1100. The controller 1120 may use a direct control of the PVD chamber 1100, or alternatively, by controlling the computers (or controllers) associated with the PVD chamber 1100. In operation, the controller 1120 enables data collection and feedback from the PVD chamber 1100 to optimize performance of the PVD chamber 1100 and to control the processing flow according to methods described herein such as depositing a PVD film as a contact transition layer on a substrate. The controller 1120 generally includes a central processing unit (CPU) 1122, a memory 1124, and a support circuit 1126. The CPU 1122 may be any form of a general-purpose computer processor that can be used in an industrial setting. The support circuit 1126 is conventionally coupled to the CPU 1122 and may comprise a cache, clock circuits, input/output subsystems, power supplies, and the like. Software routines, such as methods as described herein may be stored in the memory 1124 and, when executed by the CPU 1122, transform the CPU 1122 into a specific purpose computer (controller 1120). The software routines may also be stored and/or executed by a second controller (not shown) that is located remotely from the PVD chamber 1100.

The memory 1124 is in the form of computer-readable storage media that contains instructions, when executed by the CPU 1122, to facilitate the operation of the semiconductor processes and equipment. The instructions in the memory 1124 are in the form of a program product such as a program that implements methods of the present principles. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored, and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present principles.

The PVD chamber 1100 may be part of an integrated tool where the etching and/or other materials may be deposited to form the semiconductor structure. The advantage of using an integrated tool 1200 as depicted in FIG. 12 is that no vacuum break exists between chambers and, therefore, no requirement to degas and pre-clean a substrate before treatment or deposition in a chamber. The integrated tool 1200 includes a vacuum-tight processing platform 1201, a factory interface 1204, and a system controller 1202. The processing platform 1201 comprises multiple processing chambers, such as 1214A, 1213B, 1214C, 1214D, 1214E, and 1214F operatively coupled to a vacuum substrate transfer chamber (transfer chambers 1203A, 1203B). The factory interface 1204 is operatively coupled to the transfer chamber 1203A by one or more load lock chambers (two load lock chambers, such as 1206A and 1206B shown in FIG. 12).

In some embodiments, the factory interface 1204 comprises at least one docking station 1207, at least one factory interface robot 1238 to facilitate the transfer of the semiconductor substrates. The docking station 1207 is configured to accept one or more front opening unified pod (FOUP). Four FOUPS, such as 1205A, 1205B, 1205C, and 1205D are shown in the embodiment of FIG. 12. The factory interface robot 1238 is configured to transfer the substrates from the factory interface 1204 to the processing platform 1201 through the load lock chambers, such as 1206A and 1206B. Each of the load lock chambers 1206A and 1206B have a first port coupled to the factory interface 1204 and a second port coupled to the transfer chamber 1203A.

The load lock chamber 1206A and 1206B are coupled to a pressure control system (not shown) which pumps down and vents the load lock chambers 1206A and 1206B to facilitate passing the substrates between the vacuum environment of the transfer chamber 1203A and the substantially ambient (e.g., atmospheric) environment of the factory interface 1204. The transfer chambers 1203A, 1203B have vacuum robots 1242A, 1242B disposed in the respective transfer chambers 1203A, 1203B. The vacuum robot 1242A is capable of transferring substrates 1221 between the load lock chamber 1206A, 1206B, the processing chambers 1214A and 1214F and a cooldown station 1240 or a pre-clean station 1242. The vacuum robot 1242B is capable of transferring substrates 1221 between the cooldown station 1240 or pre-clean station 1242 and the processing chambers 1214B, 1214C, 1214D, and 1214E.

In some embodiments, the processing chambers 1214A, 1214B, 1214C, 1214D, 1214E, and 1214F are coupled to the transfer chambers 1203A, 1203B. The processing chambers 1214A, 1214B, 1214C, 1214D, 1214E, and 1214F may comprise, for example, annealing chambers, preclean chambers, ALD process chambers, PVD process chambers, remote plasma chambers, CVD chambers, or the like. In some embodiments, one or more optional service chambers (shown as 1216A and 1216B) may be coupled to the transfer chamber 1203A. The service chambers 1216A and 1216B may be configured to perform other substrate processes, such as degassing and gas treatments, and the like.

The system controller 1202 controls the operation of the integrated tool 1200 using a direct control of the process chambers 1214A, 1214B, 1214C, 1214D, 1214E, and 1214F or alternatively, by controlling the computers (or controllers) associated with the process chambers 1214A, 1214B, 1214C, 1214D, 1214E, and 1214F and the tool 1200. In operation, the system controller 1202 enables data collection and feedback from the respective chambers and systems to optimize performance of the tool 1200. The system controller 1202 generally includes a Central Processing Unit (CPU) 1230, a memory 1234, and a support circuit 1232. The CPU 1230 may be any form of a general-purpose computer processor that can be used in an industrial setting. The support circuit 1232 is conventionally coupled to the CPU 1230 and may comprise a cache, clock circuits, input/output subsystems, power supplies, and the like. Software routines, such as the methods described herein may be stored in the memory 1234 and, when executed by the CPU 1230, transform the CPU 1230 into a specific purpose computer (system controller) 1202. The software routines may also be stored and/or executed by a second controller (not shown) that is located remotely from the tool 1200.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for forming an ohmic contact of a semiconductor structure, comprising:
depositing a contact transition layer of a metal nitride material on a III-V semiconductor material, wherein the contact transition layer is at least one of hafnium nitride (HfN) or deposited using a physical vapor deposition (PVD) process; and
forming a metal layer on the contact transition layer to form the ohmic contact.

2. The method of claim 1, further comprising:
forming at least one recess on a substrate prior to depositing the contact transition layer; and
forming a mask on the substrate, wherein the at least one recess is unmasked prior to depositing the contact transition layer.

3. The method of claim 2, wherein the mask is a photoresist or dielectric material.

4. The method of claim 1, wherein the ohmic contact is a source or drain of a high electron mobility transistor (HEMT).

5. The method of claim 1, wherein the ohmic contact is a p-type contact or n-type contact of a light emitting diode (LED) structure or laser structure.

6. The method of claim 1, wherein the contact transition layer is both hafnium nitride and deposited using the PVD process.

7. The method of claim 1, wherein the metal nitride material is doped gallium nitride (GaN) when the contact transition layer is not hafnium nitride.

8. The method of claim 1, wherein the metal nitride material is doped aluminum nitride (AlN) or indium nitride (InN) when the contact transition layer is not hafnium nitride.

9. The method of claim 1, wherein the ohmic contact is a p-type contact and the hafnium nitride is p-doped hafnium nitride when the contact transition layer is hafnium nitride.

10. The method of claim 1, further comprising:
depositing the contact transition layer using a remote plasma PVD process when the contact transition layer is deposited using the PVD process.

11. The method of claim 1, further comprising:
depositing the contact transition layer at a temperature of approximately 300 degrees Celsius to approximately 900 degrees Celsius.

12. A method for forming an ohmic contact of a semiconductor structure, comprising:
forming at least one recess in a semiconductor material of a high electron mobility transistor (HEMT) structure;
depositing a contact transition layer in the at least one recess, wherein the contact transition layer is at least one of hafnium nitride (HfN) or deposited using a physical vapor deposition (PVD) process with a remote plasma source; and
forming a metal layer on the contact transition layer to form the ohmic contact for a source or drain of the HEMT.

13. The method of claim 12, wherein the hafnium nitride is undoped hafnium nitride when the contact transition layer is hafnium nitride (HfN).

14. The method of claim 12, wherein the contact transition layer is doped gallium nitride (GaN) when the contact transition layer is not hafnium nitride.

15. The method of claim 12, wherein the contact transition layer is aluminum nitride (AlN) or indium nitride (InN) when the contact transition layer is not hafnium nitride.

16. The method of claim 12, further comprising:
depositing the contact transition layer at a temperature of approximately 300 degrees Celsius to approximately 900 degrees Celsius.

17. A non-transitory, computer readable medium having instructions stored thereon that, when executed, cause a method for forming an ohmic contact of a semiconductor structure to be performed, the method comprising:
depositing a contact transition layer of a metal nitride material on a III-V semiconductor material, wherein the contact transition layer is at least one of hafnium nitride (HfN) or deposited using a physical vapor deposition (PVD) process; and
forming a metal layer on the contact transition layer to form the ohmic contact.

18. The non-transitory, computer readable medium of claim 17, the method further comprising:
forming a recess in the semiconductor structure of a high electron mobility transistor (HEMT) structure prior to depositing the contact transition layer;
forming a mask on the semiconductor structure prior to depositing the contact transition layer, wherein the recess is unmasked;
depositing the contact transition layer in the recess; and
forming the metal layer on the contact transition layer to form the ohmic contact for a source or drain of the HEMT.

19. The non-transitory, computer readable medium of claim 18, wherein the hafnium nitride is undoped hafnium nitride when the contact transition layer is hafnium nitride or the contact transition layer is doped gallium nitride (GaN) when the contact transition layer is not hafnium nitride.

20. The non-transitory, computer readable medium of claim 17, the method further comprising:
depositing the contact transition layer at a temperature of approximately 300 degrees Celsius to approximately 900 degrees Celsius.
